(19) United States
(12) Patent Application Publication
(10) Pub. No.: US 2026/0127796 A1
(43) Pub. Date: May 7, 2026

(54) METHOD FOR RECONSTRUCTING MRI IMAGES WITH CORRECTION OF OFF-RESONANCE EFFECTS

(71) Applicant: COMMISSARIAT À L'ENERGIE ATOMIQUE ET AUX ENERGIES ALTERNATIVES, PARIS (FR)

(72) Inventors: Guillaume DAVAL-FREROT, SAINTE-GENEVIEVE-DES-BOIS (FR); Aurélien MASSIRE, PALAISEAU (FR); Mariappan S. NADAR, Plainsboro, NJ (US); Boris MAILHE, Plainsboro, NJ (US); Alexandre VIGNAUD, Gif Sur Yvette (FR); Philippe CIUCIU, Gif Sur Yvette (FR)

(21) Appl. No.: 19/117,348

(22) PCT Filed: Nov. 7, 2023
(86) PCT No.: PCT/EP2023/080931

§ 371 Date: Mar. 31, 2025

Related U.S. Application Data
(60) Provisional application No. 63/382,742, filed on Nov. 8, 2022.

(51) Int. Cl. G06T 12/20; G06T 12/30

(52) U.S. Cl. CPC G06T 12/20; G06T 12/30; G06T 2211/424; G06T 2211/441

(57) ABSTRACT

A computer-implemented method for reconstructing MRI images of a body includes the steps of: a) acquiring a set MRI signal samples (s_{q}) at different k-space location along a k-space trajectory; b) acquiring or estimating a B₀ inhomogeneity map ΔB₀(r), wherein B₀ is a static magnetic field for polarizing nuclear spins of the body and r represents position in image space; c) initializing an image (f); d) updating the image by a performing a data-consistency operation in k-space, wherein conversion between image space and k-space is performed through a non-uniform discrete pseudo-Fourier transform operator taking into account the B₀ inhomogeneity map obtained from step b) to correct for off-resonance effects; and e) further updating the image by using an image-correction neural network. A computer program product and a magnetic resonance imaging apparatus for carrying out such a method is also provided.

### CROSS-REFERENCE TO RELATED APPLICATIONS

This application is a National Stage of International patent application PCT/EP2023/080931, filed on Nov. 7, 2023, which claims the benefit of U.S. Provisional Application No. 63/382,742, filed Nov. 8, 2022, the disclosures of which are incorporated by reference in their entireties.

### FIELD OF THE INVENTION

The invention relates to a method for reconstructing Magnetic Resonance Imaging (MRI) images, aimed at allowing for an efficient correction of off-resonance effect, in particular in combination with non-Cartesian k-space sampling patterns.

### BACKGROUND

Magnetic Resonance Imaging (MRI) is one of the most powerful imaging techniques used in clinical routine today, but remains a lengthy procedure, particularly when the acquisition of large and/or high resolution images, comprising several millions of pixels, is sought. For instance, acquiring a three-dimensional image of a human brain with a field of view of 205×205×52 mm³ and a 200 μm resolution using a T2* sequence with an echo time TE of 6.8 ms in a 11.7 T scanner with 8 transmit coils and 32 receive coils at an acceptable signal-to-noise ratio (SNR) of 7.6 may require an acquisition time of about two hours for a short repetition time (TR=42 ms), which is clearly unacceptable for clinical purposes.

This is because the MRI signal is transient and the excitation/acquisition procedure has to be repeated several times in order to collect informative measurements in the so-called “k-space” domain, the spatial frequency spectrum of the image, which is related to the physical space by a multidimensional Fourier transform. Sampling theory teaches that the sampling frequency should be at least twice the highest frequency contained in the signal to be sampled (which, in the case of MRI, is the multidimensional Fourier transform of the body to be imaged), otherwise aliasing artifacts will appear; this is known as the Nyquist, or Nyquist-Shannon, criterion. As a consequence, using conventional acquisition schemes, the number of k-space samples must be at least equal to the number of pixels of the image to be reconstructed. Moreover, SNR requirements impose a minimum acquisition time for each sample.

Several techniques have been developed in order to reduce the acquisition time while avoiding artifact (“accelerated MRI”). Among these techniques, Compressed Sensing (CS)—see e.g. [Lustig 2008]—is notable as it allows for order-of-magnitude higher acceleration rates compared to parallel imaging, notably while imaging with high matrix size (either high resolution and small field of view or low resolution and large field of view).

Compressed Sensing techniques rely on three principles:

The image to be reconstructed must admit a sparse (or compressible) representation. Said differently, it must be possible to decompose it on a predetermined basis (e.g. a wavelet basis) such that only a small fraction of the decomposition coefficients is non-zero for strict sparsity or significantly greater than zero for compressibility. Typically, in the case of a noisy signal, a coefficient is considered significantly greater than zero if its absolute value is at least equal to the noise standard deviation. Alternatively, only a predetermined fraction of the coefficients-those having the greatest absolute valuemay be kept. For instance, only the top 1% of the coefficient may be kept, resulting in a compression factor of 100.

Reconstruction must be performed using a nonlinear method promoting sparsity of the image representation, as well as consistency with the acquired k-space samples.

The k-space must be under-sampled in an incoherent manner, in order to accelerate the acquisition. Incoherent sampling is usually achieved using a pseudo-random under-sampling pattern. The under-sampling reduces the number of signal acquisitions, and therefore provides the required acceleration, while pseudo-randomness ensures that, in the sparsifying representation, subsampling artifacts are incoherent, i.e. decorrelated or noise-like. This incoherence property is extremely important and measures the degree of correlation between any pair of elements taken in the sparsifying (e.g., wavelets) and sensing (e.g., Fourier in CS-MRI) bases.

Compressed sensing in MRI often uses non-Cartesian pseudo-random under-sampling of k-space since this strategy provides improved incoherence (lower correlation between samples). Preferably, the pseudo-random under-sampling is non-uniform, its density matching the energy distribution of the image to be acquired in the k-space. In clinical application, this usually means using a variable density sampling which is denser near the center of the k-space (low spatial frequencies) and radially decaying towards the periphery of k-space, namely high spatial frequencies.

From a purely theoretical point of view, the pseudo-random under-sampling could be obtained by drawing the samples according to a predefined probability distribution, corresponding to the required sampling density. But in practice, the short lifespan of MR signals require samples to be acquired through segmented acquisitions along smooth trajectories which are defined by the spatial combination of time-varying magnetic field gradients applied in the two to three dimensions (2D/3D) to the body to be imaged after the excitation of its nuclear spins by a radio-frequency (RF) pulse, depending on slicewise vs volumewise (2D vs 3D) acquisition.

Commonly used k-space trajectories are parallel lines (leading to Cartesian sampling), spokes (straight lines radially diverging from the center of the k-space), rosettes, uniform-and variable-density spirals. All of them have been applied to Compressed Sensing both in 2D (slicewise) and 3D (volumewise) imaging, for instance by performing only a limited number of signal acquisitions over a Cartesian grid or by randomly sampling spokes, spirals or rosettes.

Better results, however, are achieved by using “nonparametric” trajectories that provide larger incoherence. In particular, the so-called SPARKLING (“Spreading Projection Algorithm for Rapid K-space sampLING”) technique ([Boyer 2016], [Lazarus 2017], [Lazarus 2019], [Chaithya 2022], WO2019/048565) is based on the projection of a predetermined, usually non-uniform, target sampling distribution onto the set of “admissible” 2D or 3D curves, i.e. to all the curves representing trajectories obtainable without exceeding the limits on the values of the magnetic field gradient and the corresponding slew rate.

Unfortunately non-Cartesian MRI sampling schemes are much more prone to off-resonance artifacts, due to ΔB₀, i.e. to inhomogeneities of the static magnetic field B₀, than conventional Cartesian ones. These inhomogeneities are typically located near the air/tissue interfaces around the sinuses (bucco-nasal region) or the ear canals, due to the variations in magnetic susceptibility at these interfaces. The reason is that off-resonance artifacts appear along the readout dimension, which is unidimensional (resp., multidimensional) in Cartesian sampling (resp., non-Cartesian sampling). Hence, B₀ inhomogeneities are mixed along multiple dimensions in non-Cartesian sampling which makes them more challenging to counteract.

[Chaithya 2023] has recently proposed a family of non-Cartesian k-space trajectories, called “MORE+GoLF SPARKLING” which minimizes the impact of off-resonance effects during the acquisition. Nevertheless, at least in some cases, correction of these effects during the image reconstruction step is still necessary.

Let us consider a case where M=N_{c}×Nₛ MRI samples are acquired over the k-space along a non-Cartesian multispoke sampling scheme Ω, where N_{c} is the number of spokes and Nₛ the number of samples per spoke. Let N=Nₓ×N_{y}×N_{z} the total number of voxels of the image \hat{f} to be reconstructed (represented by a N-element vector), Nₓ, N_{y} and N_{z} being the image dimensions in voxels along the x, y and z axes (the case of 3D MRI acquisition is considered here, but the same applies to 2D MRI). In the absence of B₀ inhomogeneities, the reconstructed images can be obtained from the multi-channel k-space measurements

$$s = {( {s}_{q} )}_{q = 1}^{Q}$$

by solving

$$\hat{f} = {arg min}_{f ∈ {C}^{N}} {\sum }_{q = 1}^{Q} {‖ {s}_{q} - {F}_{Ω} {S}_{q} f ‖}_{2}^{2} + R ( f ) \qquad ( 1 )$$

where f represents the object magnetization as a function of position r, R is a regularization term, Q is the number of acquisition channels (the singlechannel case can be seen as a special case of multi-channel acquisition for Q=1; Q>1 correspond to the so-called parallel imaging acquisition), S_{q} is the sensitivity map of the q^{th} acquisition channel (which can be estimated from the low frequency content of k-space data as shown in [El Gueddari 2018] using known methods and F_{Ω} is the non-uniform Fourier transform defined by

$$s ( k ( t ) ) = {\int }_{FOV} f ( r ) {e}^{- ik ( t ) r} dr \qquad ( 2 )$$

where T_{obs} is the observation time window, s(t) the acquired signal as a function of time, k(t) the k-space trajectory defined over Ω and FOV the field of view in image (physical) space. Note that in equation (1) f can take complex values, characterized by a module and a phase, which may be both of interest for clinical diagnosis.

Equation (1) can be solved iteratively through proximal gradient descent

$${w}_{k + 1} = {f}_{k} - {α}_{k} {\sum }_{q = 1}^{Q} {S}_{q}^{H} {F}_{Ω}^{H} D ( {F}_{Ω} {S}_{q} {f}_{k} - {s}_{q} ) \qquad ( 3 )$$

$${f}_{k + 1} = {prox}_{R} ( {w}_{k + 1} ) \qquad ( 4 )$$

Where indices k and k+1 (not to be conflated to a k-space location) correspond to the iteration step, Wₖ₊₁ is an auxiliary vector, prox_{R} is the proximal operator associated with R, αₖ∈R⁺ is the step size D is a density compensating operator, accounting for sample density in k-space, defined as in [Ramzi 2022] and superscript H designates conjugate transpose of complex matrices.

In order to apply ΔB₀ corrections, equation (2) has to be modified as follows:

$$s ( t ) = {\int }_{FOV} f ( r ) {e}^{- ( ik ( t ) r + Δ {ω}_{0} ( r ) t )} dr \qquad ( 5 )$$

where Δω₀(rₙ)=γΔB₀(rₙ), γ being the gyromagnetic ratio of the nuclear spins of the objects. Equation (5) can be discretized over time

$${( {t}_{m} )}_{m = 1}^{M}$$

and voxel positions

$${( {r}_{n} )}_{n = 1}^{N}$$

as follows:

$$\hat{f} ( {t}_{m} ) = {\sum }_{n = 1}^{N} \hat{f} ( {r}_{n} ) {e}^{- i {Δω}_{0} ( {r}_{n} ) {t}_{m}} {e}^{- i k ( {t}_{m} ) {r}_{n}} \qquad ( 6 )$$

The term Δω₀(rₙ)tₘ is dependent on both the k-space and image domain, which is not compatible with a regular Fourier transform. It has been proposed by [Noll 1991] to split this exponential term in a sum of products of variables that are each dependent on a single domain:

$${e}^{- i {Δω}_{0} ( {r}_{n} ) {t}_{m}} ≅ {\sum }_{l = 1}^{L} {b}_{m , l} {c}_{l , n} \qquad ( 7 )$$

This way, the term dependent on the k-space domain can be factorized out the pseudo-Fourier-transform. Equation (6) becomes than a weighted sum of L regular Fourier transforms:

$$s ( {t}_{m} ) = {\sum }_{l = 1}^{L} {b}_{m , l} {\sum }_{n = 1}^{N} f ( {r}_{n} ) {c}_{l , n} {e}^{- i k ( {t}_{m} ) {r}_{n}} \qquad ( 8 )$$

The coefficients B=(b_{m,1})∈C^{M,L} and C=(c_{l,n})∈C^{L,N} can be estimated by solving the following matrix factorization problem

$$\hat{B} , \hat{C} = {arg min}_{B = ( {b}_{m , l} ) ∈ {C}^{M , L} ; C = ( {c}_{l , n} ) ∈ {C}^{L , N}} {‖ E - BC ‖}_{F r o}^{2} \qquad ( 9 )$$

Where E_{m,n}=e^{iΔω}^{₀}^{(r}^{ₙ₎}^{t}^{ₘ} and ∥·∥_{Fro} is the Frobenius norm. The solution of problem (9) can be found by decomposing E through singular value decomposition (SVD) along either axis to obtain B or C, then finding the other one as the least square solution. This solution is known as the singular vector interpolation (SVI) coefficients.

An alternative approach, known as Multi-Frequency Interpolation (MFI)—consists in segmenting the off-resonance frequency range into L discrete values Δω_{0,l}, posing

$${b}_{m , l} = {e}^{i Δ {ω}_{0 , l} {t}_{m}} \qquad ( 10 )$$

and finding c_{l,n} through least squares.

Yet another alternative approach, known as Multi-Temporal Interpolation (MTI)—consists in segmenting the time window into L discrete values tₗ, posing

$${c}_{l , n} = {e}^{i Δ {ω}_{0} ( {r}_{n} ) {t}_{l}} \qquad ( 11 )$$

and finding b_{m,l} through least squares.

Whatever the method used for computing B and C, equation (8) defines a non-uniform discrete pseudo-Fourier transform operator F_{Ω,Σ} (with Σ representing interpolation). F_{Ω,Σ} and its adjunct operator

$${F}_{Ω , \sum }^{H}$$

can directly used to replace F_{Ω},

$${F}_{Ω , \sum }^{H}$$

in equation (3).

The computational load can be considerably reduced by taking advantage of the spoke redundancy (i.e., using the same decomposition over the N_{c} spokes) and using histograms of the ΔB₀ field map to solve a weighted version of Eq. (9), typically decreasing the image dimensions N=384×384×208 voxels to N_{b}=1000 bins (see [Fessler 2005]). This way, the matrix E is reduced from M×N to Nₛ×N_{b} and therefore correction coefficients can be obtained in a few seconds for high resolution 3D volumes.

Yet, compared to the case where no ΔB₀ correction is performed, the use of the pseudo-Fourier operator (8) and its adjoint operator increases the computational cost by a factor L, which is typically of the order of 10-20 at 3 Tesla and up to 40 at 7 Tesla to achieve satisfactory results. Indeed, the computational cost of image reconstruction in the framework described above is mostly determined by the number of calls of the Fourier operator, N_{F}, which is proportional to NlogN×I×QλL (“I” being the number of iterations of the proximal gradient algorithm of equations (3) and (4)) and this can lead to computing times of several hours (4 to 8) to reconstruct high-quality images, compared to a few minutes (10 to 15) without ΔB₀ correction.

### SUMMARY OF THE INVENTION

The invention aims at overcoming, in full or in part, the abovementioned drawback of the prior art. More particularly, it aims at reducing the computation time required for performing MRI image reconstruction with ΔB₀ correction, in particular in the case of non-Cartesian k-space sampling and/or parallel imaging acquisition.

According to the invention, this aim is achieved by combining model-based image reconstruction (i.e. reconstruction based on equation (8)) with a limited number L of interpolation components—e.g. L=5—with the use of an image correction neural network to complete the off-resonance correction. The use of the image correction neural network adds very little computational complexity and allows reducing the value of L (and optionally Q and I) without compromising the effectiveness of ΔB₀ correction and the quality of reconstructed images.

Alternating model-based image reconstruction in the k-space and neural-network based image correction in the physical space using a so-called “unrolled” architecture dedicated to non-Cartesian acquisition was known e.g. from [Ramzi 2022], but only based on conventional non-uniform Fourier transform reconstruction (i.e. without ΔB₀ correction). To the knowledge of the inventors, this is the first time such an architecture is used with pseudo-Fourier transform reconstruction for ΔB₀ correction, and it is an unexpected result that such an architecture allows for a substantial reduction of the number of interpolation components, L.

An object of the present invention is a computer-implemented method for reconstructing MRI images of a body comprising the steps of:
a) acquiring a set MR signal samples at different k-space locations along a k-space trajectory;
b) acquiring a separate a B₀ inhomogeneity map or estimating it internally, wherein B₀ is a static magnetic field for polarizing nuclear spins of the body and r represents position in image space;
c) initializing an image;
d) updating the image by a performing a data-consistency operation in k-space, wherein conversion between image space and k-space is performed through a non-uniform discrete pseudo-Fourier transform operator taking into account the B₀ inhomogeneity map obtained from step b) to correct for off-resonance effects; and
e) further updating the image by using an image-correction neural network.

Another object of the invention is a computer program product comprising instructions which, when the program is executed by a computer, cause the computer to carry out the steps of such a method.

Yet another object of the invention is a magnetic resonance imaging apparatus comprising:
a magnet or coil for generating a static magnetic field for polarizing nuclear spins of a body;
gradient coils for generating magnetic field gradients defining a k-space trajectory;
transmit coils coupled to radio-frequency pulse generators for applying radio-frequency pulses to the polarized nuclear spins at their Larmor frequency;
at least one receive coil coupled to a radio-frequency receiver for acquiring MRI signals emitted by said nuclear spins;
a processor programmed for reconstructing a MRI image of the body from the acquired MRI signals;
   characterized in that the processor is programmed for carrying out the steps of such a method.

### BRIEF DESCRIPTION OF THE DRAWINGS

Additional features and advantages of the present invention will become apparent from the subsequent description, taken in conjunction with the accompanying drawings, which show:

FIG. 1, a high-level flow-chart of a method according to the invention;

FIG. 2, a diagram of an image-reconstruction pipeline according to an embodiment of the invention;

FIGS. 3A and 3B, experimental results illustrating the technical effect of the invention; and

FIG. 4, a block diagram of a MRI scanner according to an embodiment of the invention.

### DETAILED DESCRIPTION

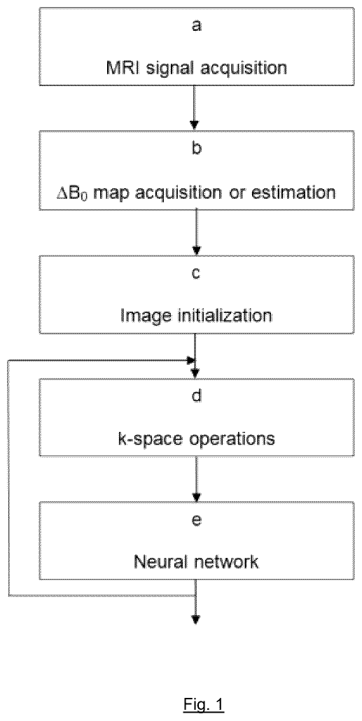

The first step—designated as step (a)—of the method of FIG. 1 consists in acquiring a set MRI signal samples at different k-space location along a k-space trajectory. The trajectory can be any known and physically feasible 2D or 3D trajectory, preferably implementing non-Cartesian sampling of the k-space. According to preferred embodiments of the invention, the trajectories may be of the SPARKLING or of the MORE+GoLF SPARKLING type. As it is well known in the art, a k-space trajectory is defined by applying suitable magnetic field gradients to a body to be imaged, whose nuclear spins are polarized by the application of a static and (approximately) uniform magnetic field B₀. Polarized nuclear spins are excited by radio-frequency pulses at the Larmor frequency γB₀ and re-emit radio-frequency MRI signals. Many different excitation RF pulse sequences are known in the art and can be used to carry out the invention. Excitation pulses and/or MRI signals may be emitted/received using a single RF coils or several coils. In case several receive coils are used (parallel MRI), their sensitivity maps S_{q} must be known to perform image reconstruction. Sensitivity maps can be obtained through external calibration, or be obtained by the MRI signals themselves (self-calibration), as thought by [El Gueddari 2018].

The second step—(b)—consists in acquiring or estimating a ΔB₀(r) map, either from a specific MRI acquisition sequence (in which case step (b) may precede step (a)) or through the MRI signal samples acquired in step (a). See e.g. [Daval-Frérot 2022].

Step (c) consists in initializing the pixelized or voxelized image to be reconstructed. For instance, initialization to zero may be used. The initialized image is designated by f₀.

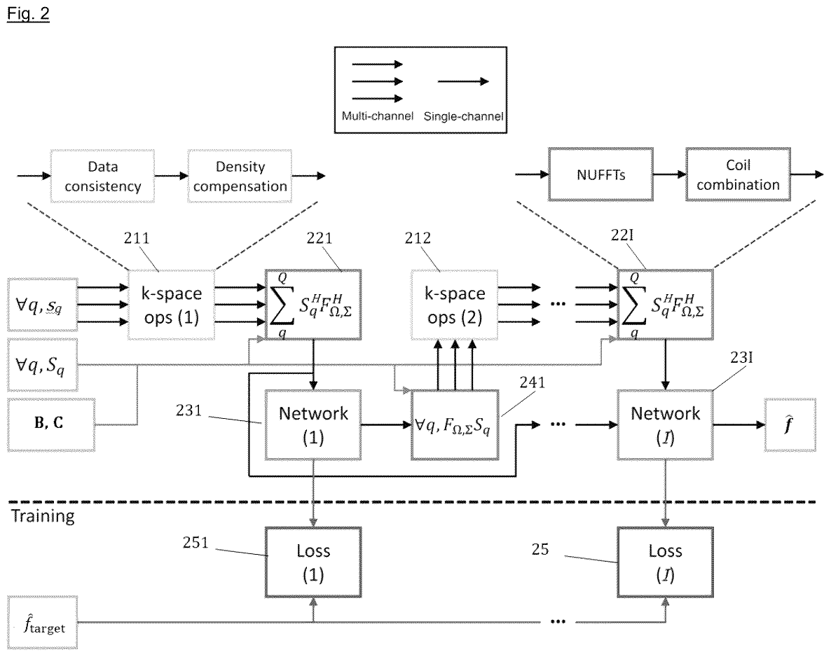

Steps (d) and (e)—which are iterated a number I≥1 and preferably |>1 of times—constitute the core of the inventive method and are illustrated in detail by FIG. 2.

In step (d), a data consistency operation, and preferably also compensation of sample density, are applied in the k-space to MRI signals s_{q} issued by all the Q receive coils. These k-space operations, represented by block 211 on FIG. 2, may be implemented by

$${f}_{0} ↦ D ( {F}_{Ω} {S}_{q} {f}_{k} - {s}_{q} ) \qquad ( 12 )$$

Then, a weighted combination of the contributions of the individual receive coils and a conversion to the physical space are performed in bloc 221, by applying the following operator to the output of block 211:

$${\sum }_{q = 1}^{Q} {S}_{q}^{H} {F}_{Ω , \sum }^{H} \qquad ( 13 )$$

where

$${F}_{Ω , \sum }^{H}$$

is the adjoint of the Non-Uniform Fast-Fourier Transform (NUFFT) operator F_{Ω,Σ} which is defined by equation (8), and depends therefore on the B₀ inhomogeneity map obtained at step (b) and from pre-computed matrices B and C.

Then, block 231 applies to the physical space data an image-correction neural network, such as a UNets or another unrolled neural network architecture (KIKI-Net, Cascade-Net, PDNet . . . ). A panorama and benchmarking of suitable neural network architectures is provided by [Ramzi 2020].

Block 241 performs a conversion to k-space by applying operator

$${F}_{Ω , \sum } {S}_{q} \qquad ( 14 )$$

to each of the Q channels.

Then, a second iteration begins with block 212, analogous to 211, and so on for I iterations. The pipeline ends with blocks 221 and 231, the output of which is the final reconstructed image \hat{f}.

Overall, the processing is analogous to the proximal gradient descent method of equations (3) and (4), where the proximal operator has been replaced by the application of a neural network for image denoising.

According to a particular embodiment, when the interpolation coefficients of the Pseudo-Fourier operator are of the SVI kind, it may be advantageous to compute matrices B and C for 2L components and alternative use a first set of L pairs of coefficients b_{m,l}, c_{l,n} corresponding to the L largest singular values and a second set of L pairs of coefficients corresponding to the L+1^{th} to 2L^{th} largest singular values. This is because SVI coefficients correspond to different regions of the off-resonance spectrum. This approach is called SVI_{1/2}.

During a training stage, all the neural network blocks 23i (i=1 to I) are trained one by one. To this aim, blocks 25i (251 . . . 251) compute a “loss” function loss 1 . . . loss l, depending from the difference between the concatenated outputs output of the first i-th neural network outputs and a target image \hat{f}_{target}. Output concatenation is instrumental in achieving the required network expressivity (in particular, to learn the step size) without the need of performing end-to-end training of the whole pipeline (including the data consistency blocks), which would entail a very large memory occupation.

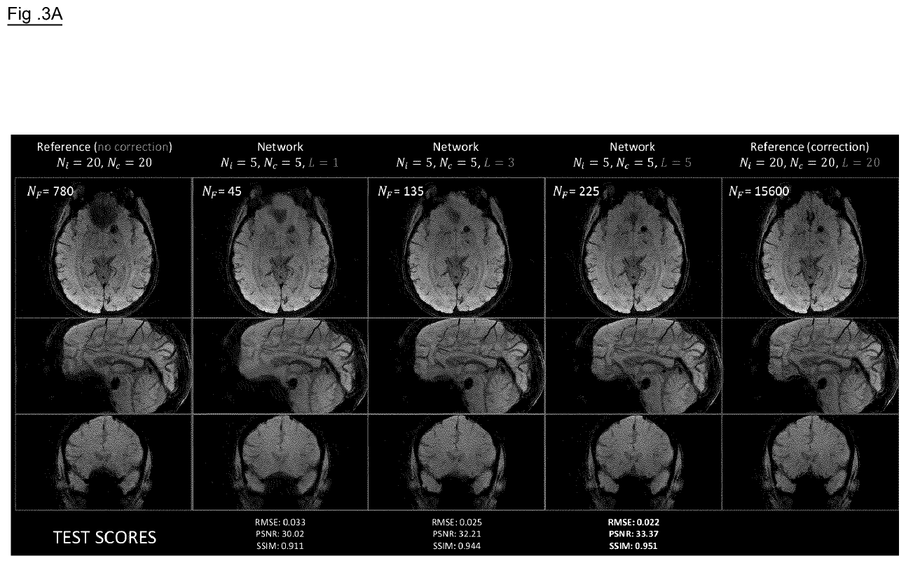

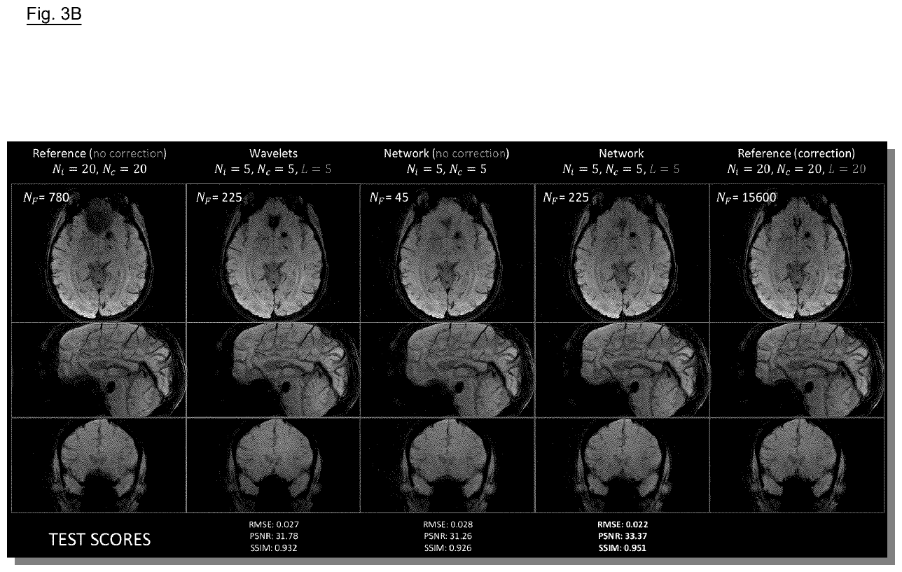

The technical effect of the invention is illustrated by FIGS. 3A and 3B, which show exemplary MRI images of a patient's head obtained by different methods. The images has been acquired using a full 3D SPARKLING trajectory with the following acquisition parameters: a field of view of 24 cm in-plane over 12.5 cm, an observation (or readout) time T_{obs} of 20.48 ms centered around an echo time TE=20 ms, a repetition time TR=37 ms, a varying number of spokes, N_{c}, and Nₛ=2048 samples per spoke. This images are representative of a larger dataset (99 patients for training, 11 for validation and 11 for testing, of both sexes, with ages ranging from 18 to 90 and body mass index values comprised between 16.5 and 40).

The lines of FIG. 3A and FIG. 3B correspond to axial, sagittal and coronal slices (or views) of 3D images of the brain of a same patient (from top to bottom). The different columns correspond to different reconstruction methods.

The first columns of FIG. 3A corresponds to a case according to the prior art, where image reconstruction is performed by proximal gradient descent without ΔB₀ correction (equations (3) and (4)), by taking Nᵢ=20 and N_{c}=20, corresponding to N_{F}=780. Very strong artifacts are visible, in particular in the bucco-nasal region (top of the first line, left part of the second line, bottom of the third line).

The fifth column of FIG. 3A corresponds to another case according to the prior art, where ΔB₀ correction is performed using a modified proximal gradient descent algorithm using the pseudo-Fourier operation of equation (8)—also called “wavelet” approach—with L=20 interpolation components. Comparison with the images of the first column shows that the artifacts have substantially disappeared; however, the choice of Nᵢ=20, N_{c}=20 and L=20 leads to N_{F}=15600, which corresponds to a very long reconstruction time, e.g. of the order of 8 hours. This image is taken as a reference to evaluate the performances of alternative reconstruction methods.

The second, third and fourth columns (from left to right) of FIG. 3A correspond to different implementations of the inventive method, applying both a pseudo-Fourier operator and a neural network to correct for ΔB₀ effects. In the case of the second column Nᵢ=5, N_{c}=5 and L=1, corresponding to N_{F}=45, itt can be seen that the use of a single interpolation term already leads to a significant reduction of artifacts compared to the “nocorrection” case of the first column. A further reduction of artifact is obtained for Nᵢ=5, N_{c}=5, L=3→N_{F}=135 (third column) and for Nᵢ=5, N_{c}=5, L=5→N_{F}=225 (fourth column). In the latter case—corresponding to a reduction of computation time in excess of a factor of 60 compared to the reference time (i.e. from several hours to a few minutes)—a residual blur is only visible in the immediate proximity of the nasal sinuses.

The first, fourth and fifth (last) column of FIG. 3B are identical to the corresponding columns of FIG. 3A. FIG. 2A corresponds to wavelet reconstruction with the same parameters (and therefore approximately the same computation time) as in the fourth column, i.e. Nᵢ=5, N_{c}=5, L=5→N_{F}=225. Artifacts are much more apparent, confirming that the inventive method is much more effective than the prior art wavelet approach in compensating for ΔB₀.

The third column of FIG. 3B corresponds to image reconstruction using a Fourier operator and a neural network, but without ΔB₀ correction. Image quality is comparable to that of the second column, and much lower than that of the fourth column, confirming the importance of ΔB₀ correction.

Quantitative assessment of image quality for the second, third and fourth columns of both FIGS. 3A and 3B can be performed by computing root mean square error (RMSE), the Peak Signal-t-Noise Ratio (PSNR, expressed in dB) the Structural SIMilarity index (SSIM, ranging from 0 to 1) compared to the fifth column case (i.e. to the “optimal” reconstruction). These metrics are defined in [Ramzi 2020] and their values for the different cases considered here are reproduced on the figures.

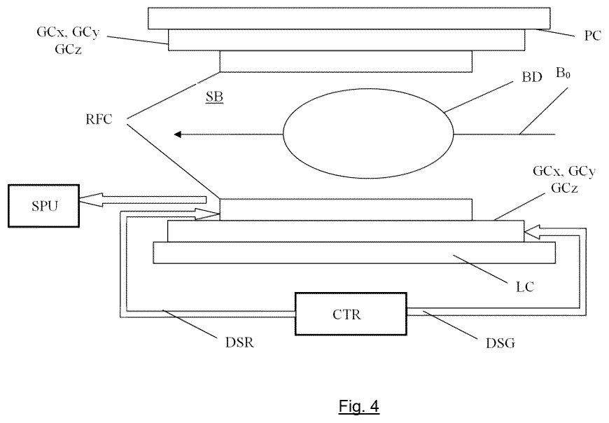

FIG. 4 illustrates, very schematically, an apparatus for carrying out a method according to the invention. This apparatus is basically a MRI scanner comprising a magnet or primary coil PC for generating the static magnetic field B₀, a single or preferably a plurality of radio-frequency coils TC for generating RF pulses and receiving the NMR signal (different radio-frequency coils may be used for transmission and reception, or the same coils may serve for both purposes), three gradient coils GCx, GCy and GCz for generating magnetic field gradients Gₓ, G_{y}, G_{z} along the x, y and z axes respectively (not represented). The gradient coils are disposed around a scanner bore SB in which a body BD to be imaged can be introduced. The term “body” should be construed broadly, designating any living or non-living object containing atomic nuclei at least some of which are supposed to have non-zero spin. For instance, body BD may be a human or animal body or a portion thereof (e.g. a head) or an article of manufacture such as a “phantom”. The apparatus also comprises a control unit CTR for driving said gradient coils in and said radio-frequency coil or coils according to a predetermined driving signal (reference DSR for the radio-frequency coils and DSG for the gradient coils) to implement a readout sequence and a (preferably non-Cartesian) k-space trajectory, respectively. The apparatus also comprises a signal processing unit SPU for acquiring NMR signals from the radio-frequency coil or coils and performing image reconstruction. The control unit and the signal processing unit may be separate devices or a single device may implement both functions. Said device or devices may include one or more suitably programmed general purpose computers or digital signal processors, suitably configured specialized digital circuits or both. The signal processing unit also includes a receiving circuit for acquiring NMR signals, comprising a signal amplifier, a sampler and an analog to digital (ADC) converter.

The scanner of FIG. 4 differs from the prior art essentially in that the signal processing unit SPU is configured or programmed for performing image reconstruction according to the inventive method.

### NON-PATENT REFERENCES

[Boyer 2016] Boyer, Claire, et al. “On the generation of sampling schemes for magnetic resonance imaging.” SIAM Journal on Imaging Sciences 9.4 (2016): 2039-2072.
[Chaithya 2020] Chaithya G R et al. “Optimizing full 3D SPARKLING trajectories for high-resolution T2*—weighted MagneticResonance Imaging. 2020 arXiv preprint arXiv:2108.02991 & IEEE Transactions on Medical Imaging, 2022.
[Chaithya 2023] Chaithya G R et al “Improving spreading projection algorithm for rapid k-space sampling trajectories through minimized off-resonance effects and gridding of low frequencies.” Magnetic Resonance in Medicine (2023).
[Daval-Frérot 2022] Daval-Frérot G. et al. “Iterative static field map estimation for off-resonance correction in non-Cartesian susceptibility weighted imaging” Magnetic Resonance in Medicine (2022).
[El Gueddari 2018] El Gueddari L, et al. “Self-calibrating nonlinear reconstruction algorithms for variabledensity sampling and parallel reception MRI” 2018 IEEE 10th Sensor Array and Multichannel Signal Processing Workshop (SAM). IEEE; 2018:415-419.
[Fessler 2005] Fessler J. A. et al. “Toeplitz based iterative image reconstruction for MRI with correction for magnetic field inhomogeneity”. IEEE Trans Signal Process. 2005; 53:3393-3402.
[Lazarus 2017] Lazarus, Carole, et al. “SPARKLING: Novel Non-Cartesian Sampling Schemes for Accelerated 2D Anatomical Imaging at 7T Using Compressed Sensing.” 25th annual meeting of the International Society for Magnetic Resonance Imaging, April 2017, Honolulu, United States.
[Lazarus 2019] Lazarus, Carole et al. “SPARKLING: variable-density k-space filling curves for accelerated T 2*-weighted MRI” Magnetic Resonance in Medicine, Wiley, 2019, 81 (6), pp. 3643-3661.
[Lustig 2007] Lustig M., Donoho D., Pauly J. M. Sparse MRI: The application of compressed sensing for rapid M R imaging”. Magn Reson Med 2007; 58:1182-1195
[Ramzi 2020] Ramzi, Z. et al. Benchmarking MRI Reconstruction Neural Networks on Large Public Datasets”, Appl. Sci. 2020, 10, 1816
[Ramzi 2022] Ramzi Z. et al. “N C-PDNet: a DensityCompensated Unrolled Networkfor 2D and 3D non-Cartesian MRI Reconstruction” IEEE Transactions on Medical Imaging, 2022, 10.1109/TMI.2022.3144619.

1. A computer-implemented method for reconstructing MRI images of a body (BD) comprising the steps of:
a) acquiring a set MRI signal samples (s_{q}) at different k-space location along a k-space trajectory;
b) acquiring or estimating a B₀ inhomogeneity map ΔB₀(r), wherein B₀ is a static magnetic field for polarizing nuclear spins of the body and r represents position in image space;
c) initializing an image (f);
d) updating the image by a performing a data-consistency operation in k-space, wherein conversion between image space and k-space is performed through a non-uniform discrete pseudo-Fourier transform operator taking into account the B₀ inhomogeneity map obtained from step b) to correct for off-resonance effects; and
e) further updating the image by using an image-correction neural network (231).

2. The method of claim 1, wherein steps d) and e) are iterated a plurality of times.

3. The method of claim 1, wherein step d) is performed by decomposing said non-uniform discrete pseudo-Fourier transform operator into a sum of non-uniform discrete Fourier transform operators weighted by interpolation coefficients.

4. The method of claim 3, wherein said non-uniform pseudo-Fourier transform operator F_{Ω}, decomposed into a sum of non-uniform discrete Fourier transform operators weighted by interpolation coefficients, is defined by
$$s = {F}_{Ω , \sum } f$$
where s is a M-component vector representing M>1 signal samples sₘ acquired at respective times tₘ at k-space locations kₘ=k(tₘ), k being the k-space trajectory, with m ranging from 1 to M and f is a N-component vector representing N>1 pixels or voxels of the real-space image xₙ corresponding to positions rₙ and
$${s}_{m} = {\sum }_{l} {b}_{m , l} {\sum }_{n} {f}_{n} {c}_{l , n} {e}^{- i {k}_{m} {r}_{n}}$$
Index l ranging from 1 to L, L>1 being the number of said non-uniform discrete Fourier transform operators, and coefficients b_{m,l} and c_{l,n} are such that
$${\sum }_{l} {b}_{m , l} {c}_{l , n}$$
constitutes an approximation of
$${e}^{i Δ {ω}_{0} ( {r}_{n} ) {t}_{m}}$$
with Δω₀(rₙ)=γΔB₀(rₙ), γ being the gyromagnetic ratio of the nuclear spins.

5. The method of claim 4, wherein said interpolation coefficients are obtained through singular value decomposition of E_{m,n}=e^{iΔω}^{₀}^{(r}^{ₙ}^{)t}^{ₘ}.

6. The method of claim 5, wherein steps d) and e) are iterated a plurality of times, and wherein different sets of coefficients b_{m,l} and c_{l,n}, corresponding to different singular values of E, are used in successive iterations of steps d) and e).

7. The method of claim 1, wherein step a) is performed by parallel acquisition using Q>1 receive coils (RFC), signal samples issued by said receive coils being combined during step d) through respective sensitivity maps.

8. The method of claim 1, wherein the data consistency operation of step d) is
$$f ↦ f - α {\sum }_{q = 1}^{Q} {S}_{q}^{H} {F}_{Ω , \sum }^{H} D ( {F}_{Ω , \sum } {S}_{q} f - {s}_{q} )$$
Wherein Q≥1 is the number of receive coils acquiring MRI signal samples, s_{q} is the vector of signal samples acquired by the q-th receive coil, f is a pixel or voxel vector representing the image, α is a positive real value, F_{Ω} is the non-uniform discrete pseudo-Fourier transform operator, S_{q} a sensitivity map of the q-th receive coil, D is a density compensation operator and superscript H designates conjugate transpose of complex matrices.

9. The method of claim 1, wherein the image-correction neural network used in step e) is a fully convolutional neural network.

10. The method of claim 9, wherein the image-correction neural network is a Unet.

11. The method of claim 9, wherein steps d) and e) are iterated a plurality of times, and wherein each iteration of step e) uses a different image-correction neural network, trained based on a dataset comprising the outputs of all preceding iterations of step d).

12. The method of claim 1, wherein the k-space trajectory defines a non-Cartesian sampling of k-space.

13. The method of claim 12, wherein the k-space trajectory is a continuous trajectory such that the k-space locations where samples are acquired define a pseudo-random sampling of the k-space, matching a predetermined target sampling density.

14. A computer program product comprising instructions which, when the program is executed by a computer (SPU), cause the computer to carry out the steps of the method of claim 1.

15. A magnetic resonance imaging apparatus comprising:
a magnet or coil (PC) for generating a static magnetic field (B₀) for polarizing nuclear spins of a body (BD);
gradient coils (GCx, GCy, GCz) for generating magnetic field gradients defining a k-space trajectory;
transmit coils (RFC) coupled to radio-frequency pulse generators for applying radio-frequency pulses to the polarized nuclear spins at their Larmor frequency;
at least one receive coil (RFC) coupled to a radio-frequency receiver for acquiring MRI signals emitted by said nuclear spins;
a processor programmed (SPU) for reconstructing a MRI image of the body from the acquired MRI signals;
wherein the processor is programmed for carrying out the steps of the method of claim 1.
